(19) United States
(12) Patent Application Publication
(10) Pub. No.: US 2012/0303363 A1
(43) Pub. Date: Nov. 29, 2012

(54) Processing Audio Signals

(75) Inventor: Karsten Vandborg Sorensen, Stockholm (SE)

(73) Assignee: Skype Limited, Dublin (IE)

(21) Appl. No.: 13/212,633

(22) Filed: Aug. 18, 2011

(30) Foreign Application Priority Data
May 26, 2011 (GB) 1108885.3

(51) Int. Cl. G10L 19/14; H03G 3/00

(52) U.S. Cl. 704/225; 381/107; 704/E19.039

(57) ABSTRACT

A method, user device and computer program product for processing audio signals during a communication session between a user device and a remote node. The method comprising: receiving a plurality of audio signals at audio input means at the user device including at least one primary audio signal and unwanted signals; receiving direction of arrival information of the audio signals at a gain control means; providing to the gain control means known direction of arrival information representative of at least some of said unwanted signals; processing the audio signals at the gain control means by applying a level of gain to generate a gain controlled signal for transmission to the remote node, wherein the level of gain applied is dependent on a comparison between the direction of arrival information of the audio signals and the known direction of arrival information.

### RELATED APPLICATION

This application claims priority under 35 U.S.C. §119 or 365 to Great Britain Application No. GB 1108885.3, filed May 26, 2011. The entire teachings of the above application are incorporated herein by reference.

### TECHNICAL FIELD

This invention relates to processing audio signals during a communication session.

### BACKGROUND

Communication systems allow users to communicate with each other over a network. The network may be, for example, the internet or the Public Switched Telephone Network (PSTN). Audio signals can be transmitted between nodes of the network, to thereby allow users to transmit and receive audio data (such as speech data) to each other in a communication session over the communication system.

A user device may have audio input means such as a microphone that can be used to receive audio signals, such as speech from a user. The user may enter into a communication session with another user, such as a private call (with just two users in the call) or a conference call (with more than two users in the call). The user's speech is received at the microphone, processed and is then transmitted over a network to the other user(s) in the call.

As well as the audio signals from the user, the microphone may also receive other audio signals, such as background noise, which may disturb the audio signals received from the user.

The user device may also have audio output means such as speakers for outputting audio signals to the user that are received over the network from the user(s) during the call. However, the speakers may also be used to output audio signals from other applications which are executed at the user device. For example, the user device may be a TV which executes an application such as a communication client for communicating over the network. When the user device is engaging in a call, a microphone connected to the user device is intended to receive speech or other audio signals provided by the user intended for transmission to the other user(s) in the call. However, the microphone may pick up unwanted audio signals which are output from the speakers of the user device. The unwanted audio signals output from the user device may contribute to disturbance to the audio signal received at the microphone from the user for transmission in the call.

A problem can also arise when the user device is used in a room with other sources of noise which can be picked up by the microphone.

In order to improve the quality of the signal, such as for use in the call, it is desirable to suppress unwanted audio signals (the background noise and the unwanted audio signals) that are received at the audio input means of the user device.

The use of stereo microphones and microphone arrays in which a plurality of microphones operate as a single device are becoming more common. These enable the use of extracted spatial information in addition to what can be achieved in a single microphone. When using such devices one approach to suppress unwanted audio signals is to apply a beamformer. Beamforming is the process of trying to focus the signals received by the microphone array by applying signal processing to enhance sounds coming from one or more desired directions. For simplicity we will describe the case with only a single desired direction in the following, but the same method will apply when there are more directions of interest. The beamforming is achieved by first estimating the angle from which wanted signals are received at the microphone, so-called Direction of Arrival (“DOA”) information. Adaptive beamformers use the DOA information to process the signals from the microphones in an array to form one or more beams with a high gain in directions from which wanted signals are received at the microphone array and a low gain in any other direction.

While the beamformer will attempt to suppress the unwanted audio signals coming from unwanted directions, the number of microphones as well as the shape and the size of the microphone array will limit the effect of the beamformer, and as a result the unwanted audio signals are suppressed, but remain audible.

For subsequent single channel processing, the output of the beamformer is commonly supplied to an Automatic Gain Control (AGC) processing stage as an input signal. The AGC processing stage applies gain to the whole signal on the channel and adjusts the gain over time to an appropriate level based on the input signal level.

When there is far-end activity it can be estimated from which direction(s) the echo is arriving from the loudspeaker(s). The same loudspeakers can be used to play out, e.g., music, or if the end-point is a TV it can be audio from the currently viewed program. When the speakers are playing out audio other than far-end speech, it would normally be classified as near-end activity, and the automatic gain controls would amplify it to regular speech levels. When the near-end speaker then speaks the automatic gain controls would have adjusted for the wrong signal, and would have to re-adjust to the near-end speech. During the time it takes to adjust back to the optimum gain the signal can be clipped and/or heavily compressed or the signal amplitude (i.e. volume) can be too low when comparing to a target level representing audible speech.

### SUMMARY

In the following described embodiments of the invention, the information about the angle from which sound is arriving can be used also for automatic analogue and digital gain control. The DOA information is used to make the gain control robust to audio that is arriving from certain directions. With embodiments of the current invention, it would be detected that the audio is arriving from the angle of the speakers and we would keep the gain constant until the sound again is arriving from the angle(s) of the (human) near-end speaker(s). Thus, it would be prevented that the gain is increased for sounds that are arriving from undesired directions.

According to a first aspect of the invention there is provided a method of processing audio signals during a communication session between a user device and a remote node, the method comprising: receiving a plurality of audio signals at audio input means at the user device including at least one primary audio signal and unwanted signals; receiving direction of arrival information of the audio signals at a gain control means; providing to the gain control means known direction of arrival information representative of at least some of said unwanted signals; and processing the audio signals at the gain control means by applying a level of gain to generate a gain controlled signal for transmission to the remote node, wherein the level of gain applied is dependent on a comparison between the direction of arrival information of the audio signals and the known direction of arrival information.

Preferably, the audio input means processes the plurality of audio signals to generate a single channel audio output signal comprising a sequence of frames, the gain control means processing each of said frames in sequence.

Preferably, the direction of arrival of information for a principal signal component of a current frame being processed is received at the gain control means, the method further comprising: comparing the direction of arrival of information for the principal signal component of the current frame and the known direction of arrival information. A determination on whether to inhibit the activity of the gain control means may be made based on said comparison.

The known direction of arrival information may include at least one direction from which far-end signals are received at the audio input means, said determination based on whether the principal signal component of the current frame is received at the audio input means from the at least one direction from which far-end signals are received at the audio input means.

Alternatively or additionally, the known direction of arrival information may include at least one classified direction, said determination based on whether the principal signal component of the current frame is received at the audio input means from the at least one classified direction, the at least one classified direction may be a direction from which at least one unwanted audio signal arrives at the audio input means and is identified based on the signal characteristics of the at least one unwanted audio signal.

Alternatively or additionally, the known direction of arrival information may include at least one principal direction from which the at least one primary audio signal is received at the audio input means, said determination based on whether the principal signal component of the current frame is received at the audio input means from the at least one principal direction.

Preferably, the at least one principal direction is determined by: determining a time delay that maximises the cross-correlation between the audio signals being received at the audio input means; and detecting speech characteristics in the audio signals received at the audio input means with said time delay of maximum-cross correlation.

The audio input means may comprise a beamformer arranged to: estimate the at least one principal direction; and process the plurality of audio signals to generate the single channel audio output signal by forming a beam in the at least one principal direction and substantially suppressing audio signals from any direction other than the principal direction. The known direction of arrival information may include the beam pattern of the beamformer.

If it determined from said comparison that the activity of said gain control means is to be inhibited, the gain control means may be configured to apply a level of gain to the current frame being processed that was applied to a frame processed immediately prior to the current frame. Alternatively, if it determined from said comparison that the activity of said gain control means is to be inhibited, the gain control means may be configured to apply a level of gain to the current frame in dependence on a signal level of a frame processed immediately prior to the current frame, subject to a change in gain between the current and prior frame being capped.

If it determined from said comparison that the activity of said gain control means is not to be inhibited the gain control means may be configured to compare a signal level of the frame processed with a signal level of a frame processed immediately prior to the current frame; and if the signal level of the current frame is higher than the signal level of the frame processed immediately prior to the current frame, the gain control means configured to decrease a level of gain and apply the decreased level of gain to the current frame; and if the signal level of the current frame is lower than the signal level of the frame processed immediately prior to the current frame the gain control means configured to increase the level of gain and apply the increased level of gain to the current frame.

In one embodiment, the audio input means comprises first and second audio input means, each audio input means processing the plurality of audio signals to generate an output channel, the method further comprising: processing each output channel at respective gain control means by applying a level of gain to each output channel to generate first and second gain controlled signals for transmission to the remote node, wherein the level of gain is dependent on the comparison between the direction of arrival information of the audio signals and the known direction of arrival information, and is the same for each output channel.

Preferably, audio data received at the user device from the remote node in the communication session is output from audio output means of the user device.

The unwanted signals may be generated by a source at the user device, said source comprising at least one of: audio output means of the user device; a source of activity at the user device wherein said activity includes clicking activity comprising button clicking activity, keyboard clicking activity, and mouse clicking activity.

Alternatively the unwanted signals may be generated by a source external to the user device.

Preferably, the at least one primary audio signal is a speech signal received at the audio input means.

According to a second aspect of the invention there is provided a user device for processing audio signals during a communication session between a user device and a remote node, the user terminal comprising: audio input means for receiving a plurality of audio signals including a at least one primary audio signal and unwanted signals; and gain control means for receiving direction of arrival information of the audio signals and known direction of arrival information representative of at least some of said unwanted signals, the gain control means configured to process the audio signals by applying a level of gain to generate a gain controlled signal for transmission to the remote node, wherein the level of gain applied is dependent on a comparison between the direction of arrival information of the audio signals and the known direction of arrival information.

According to a third aspect of the invention there is provided a computer program product comprising computer readable instructions for execution by computer processing means at a user device for processing audio signals during a communication session between the user device and a remote node, the instructions comprising instructions for carrying out the method according to the first aspect of the invention.

### BRIEF DESCRIPTION OF THE DRAWINGS

For a better understanding of the present invention and to show how the same may be put into effect, reference will now be made, by way of example, to the following drawings in which:

FIG. 1 shows a communication system according to a preferred embodiment;

FIG. 2 shows a schematic view of a user terminal according to a preferred embodiment;

FIG. 3 shows an example environment of the user terminal;

FIG. 4a shows a schematic diagram of audio input means at the user terminal according to one embodiment;

FIG. 4b shows a schematic diagram of audio input means at the user terminal according to an alternative embodiment;

FIG. 5 shows a diagram representing how DOA information is estimated;

FIG. 6 illustrates two approaches that may be used to adjust the level of gain applied to an audio channel.

### DETAILED DESCRIPTION OF THE INVENTION

In the following embodiments of the invention, a technique is described in which, instead of fully relying on the beamformer to attenuate sounds that are not coming from the direction of focus, using the DOA information in the automatic gain controls explicitly increases robustness to sounds from any other direction. This is a significant advantage when the undesired signal can be distinguished from the desired near-end speech signal by using spatial information. Examples of such sources are loudspeakers playing music, fans blowing, and doors closing.

By using signal classification the direction of other sources can also be found. Examples of such sources could be, e.g. cooling fans/air conditioning systems, music playing in the background, and keyboard taps.

Two complementary approaches can be taken. Firstly, undesired sources that are arriving from certain directions can be identified and the angles excluded from the angles that the gain controls are permitted to react to.

Secondly, the gain control can be made less sensitive to any other direction than the ones where we expect near-end speech to arrive from. The second method would ensure that there is no adjustment based on moving noise sources which do not arrive from the same direction as the primary speaker(s), and which also have not been detected to be a source of noise.

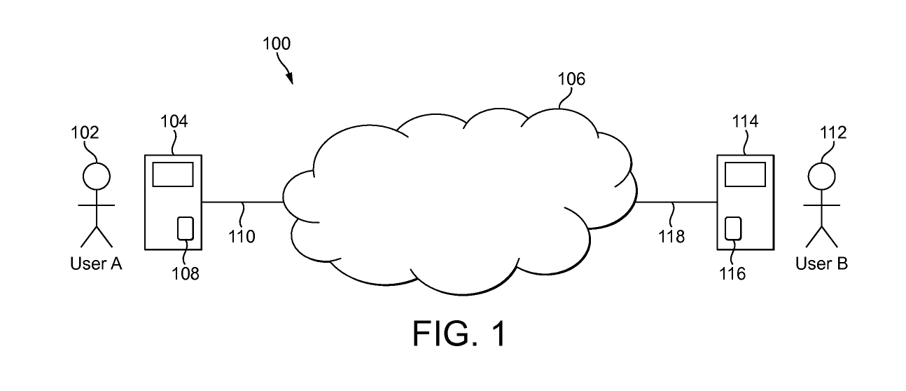

Reference is first made to FIG. 1, which illustrates a communication system 100 of a preferred embodiment. A first user of the communication system (User A 102) operates a user device 104. The user device 104 may be, for example a mobile phone, a television, a personal digital assistant (“PDA”), a personal computer (“PC”) (including, for example, Windows™, Mac OS™ and Linux™ PCs), a gaming device or other embedded device able to communicate over the communication system 100.

The user device 104 comprises a central processing unit (CPU) 108 which may be configured to execute an application such as a communication client for communicating over the communication system 100. The application allows the user device 104 to engage in calls and other communication sessions (e.g. instant messaging communication sessions) over the communication system 100. The user device 104 can communicate over the communication system 100 via a network 106, which may be, for example, the Internet or the Public Switched Telephone Network (PSTN). The user device 104 can transmit data to, and receive data from, the network 106 over the link 110.

FIG. 1 also shows a remote node with which the user device 104 can communicate over the communication system 100. In the example shown in FIG. 1, the remote node is a second user device 114 which is usable by a second user 112 and which comprises a CPU 116 which can execute an application (e.g. a communication client) in order to communicate over the communication network 106 in the same way that the user device 104 communicates over the communications network 106 in the communication system 100. The user device 114 may be, for example a mobile phone, a television, a personal digital assistant (“PDA”), a personal computer (“PC”) (including, for example, Windows™, Mac OS™ and Linux™ PCs), a gaming device or other embedded device able to communicate over the communication system 100. The user device 114 can transmit data to, and receive data from, the network 106 over the link 118. Therefore User A 102 and User B 112 can communicate with each other over the communications network 106.

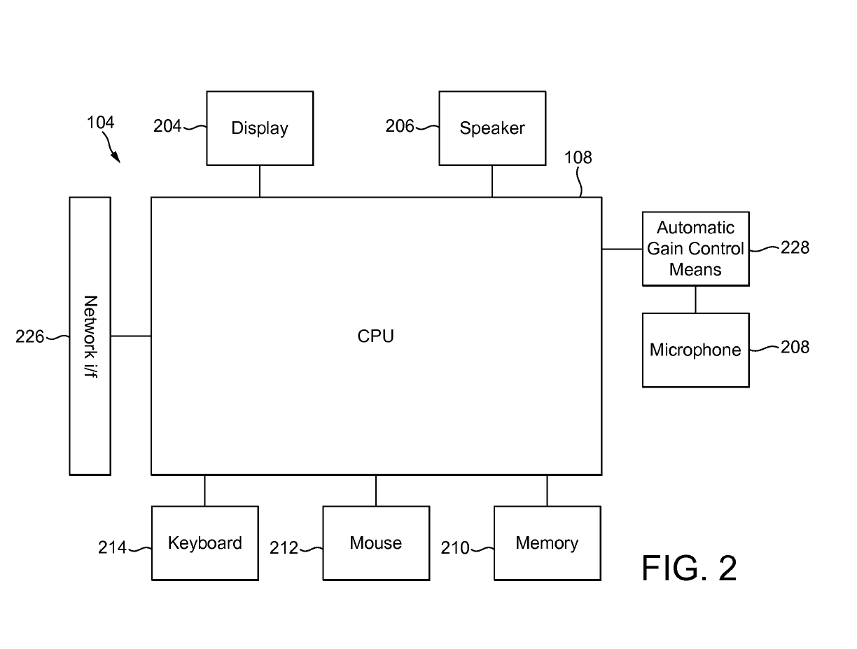

FIG. 2 illustrates a schematic view of the user terminal 104 on which the client is executed. The user terminal 104 comprises a CPU 108, to which is connected a display 204 such as a screen, memory 210, input devices such as keyboard 214 and a pointing device such as mouse 212. The display 204 may comprise a touch screen for inputting data to the CPU 108. An output audio device 206 (e.g. a speaker) is connected to the CPU 108. An input audio device such as microphone 208 is connected to the CPU 108 via automatic gain control means 228. Although the automatic gain control means 228 is represented in FIG. 2 as a standalone hardware device, the automatic gain control means 228 could be implemented in software. For example the automatic gain control means could be included in the client.

The CPU 108 is connected to a network interface 226 such as a modem for communication with the network 106.

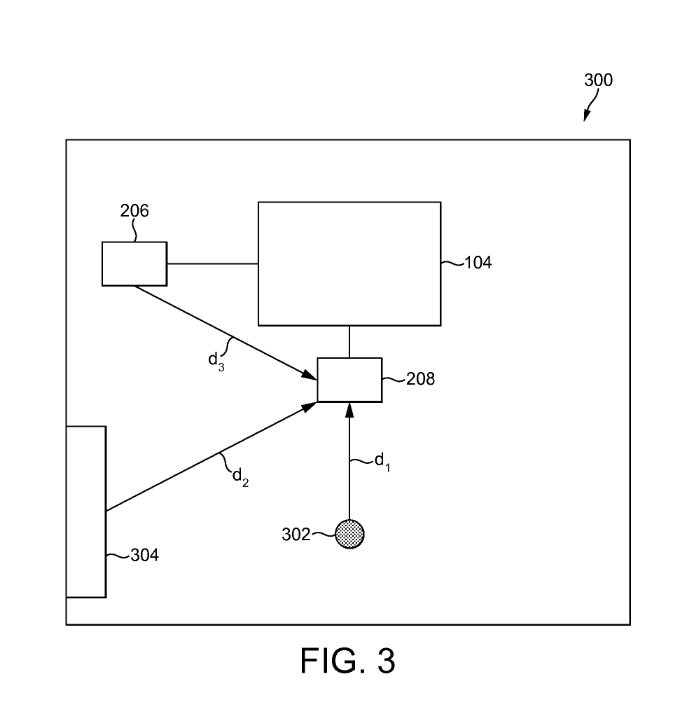

Reference is now made to FIG. 3, which illustrates an example environment 300 of the user terminal 104.

Desired audio signals are identified when the audio signals are processed after having been received at the microphone 208. During processing, desired audio signals are identified based on the detection of speech like characteristics and a principal direction of a main speaker is determined. This is shown in FIG. 3 where the main speaker (user 102) is shown as a source 302 of desired audio signals that arrives at the microphone 208 from a principal direction d1. Whilst a single main speaker is shown in FIG. 3 for simplicity, it will be appreciated that any number of sources of wanted audio signals may be present in the environment 300.

Sources of unwanted noise signals may be present in the environment 300. FIG. 3 shows a noise source 304 of an unwanted noise signal in the environment 300 that may arrive at the microphone 208 from a direction d3. Sources of unwanted noise signals include for example cooling fans, air-conditioning systems, and a device playing music.

Unwanted noise signals may also arrive at the microphone 208 from a noise source at the user terminal 104 for example clicking of the mouse 212, tapping of the keyboard 214, and audio signals output from the speaker 206. FIG. 3 shows the user terminal 104 connected to microphone 208 and speaker 206. In FIG. 3, the speaker 206 is a source of an unwanted audio signal that may arrive at the microphone 208 from a direction d2.

Whilst the microphone 208 and speaker 206 have been shown as external devices connected to the user terminal it will be appreciated that microphone 208 and speaker 206 may be integrated into the user terminal 104.

In conventional methods, the AGC processing stage will adjust the level of gain on the whole channel to an appropriate level in dependence on the input signal level. Any unwanted noise signals that are received from unwanted directions that are present at the input of the AGC processing stage will be amplified to regular speech levels by the AGC processing stage whenever the noise signals are mistaken for speech. This affects the transmitted speech quality in the call.

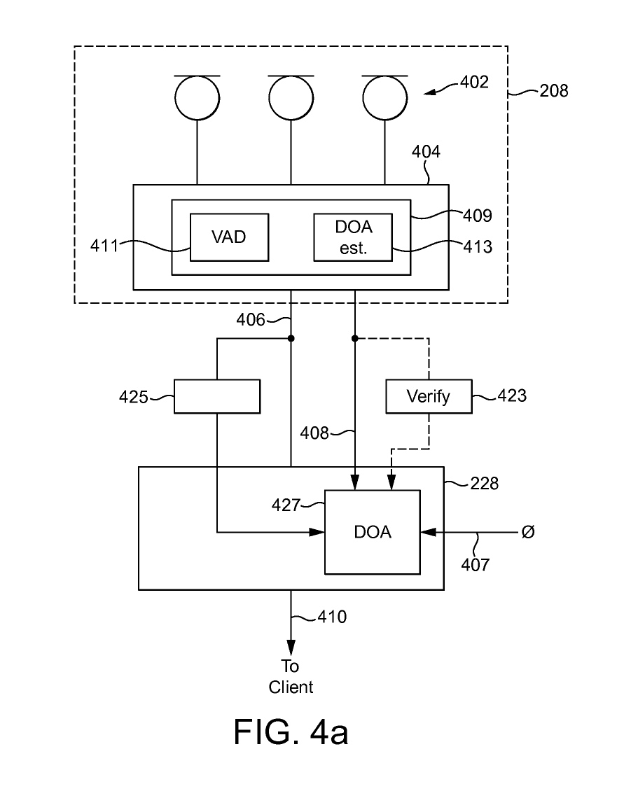

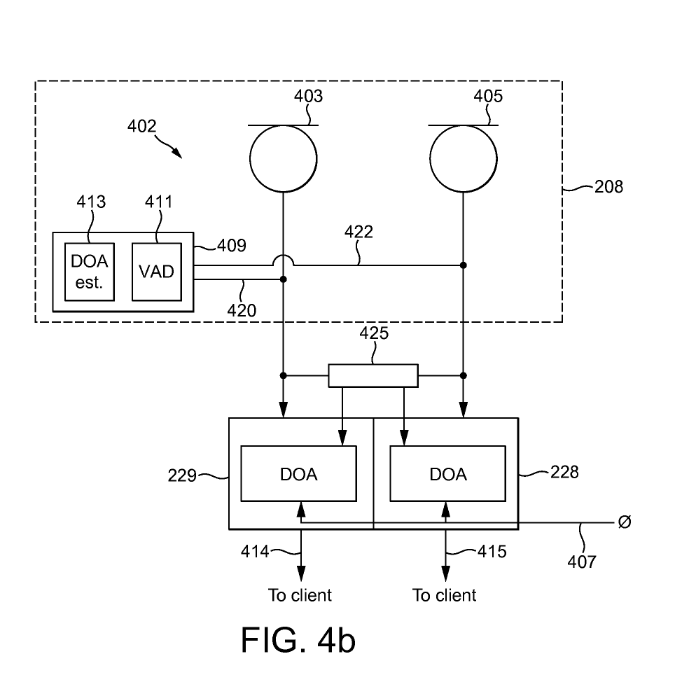

Reference is now made to FIG. 4a which illustrates a more detailed view of microphone 208 and the automatic gain control means 228 according to one embodiment.

Microphone 208 includes a microphone array 402 comprising a plurality of microphones, and a beamformer 404. The output of each microphone in the microphone array 402 is coupled to the beamformer 404. Persons skilled in the art will appreciate that to implement beamforming multiple inputs are needed. The microphone array 402 is shown in FIG. 4 as having three microphones, it will be understood that this number of microphones is merely an example and is not limiting in any way.

The beamformer 404 includes a processing block 409 which receives the audio signals from the microphone array 402. Processing block 409 includes a voice activity detector (VAD) 411 and a DOA estimation block 413 (the operation of which will be described later). The processing block 409 ascertains the nature of the audio signals received by the microphone array 402 and based on detection of speech like qualities detected by the VAD 11 and DOA information estimated in block 413, one or more principal direction(s) of main speaker(s) is determined. The beamformer 404 uses the DOA information to process the audio signals by forming a beam that has a high gain in the direction from the one or more principal direction(s) from which wanted signals are received at the microphone array and a low gain in any other direction. Whilst it has been described above that the processing block 409 can determine any number of principal directions, the number of principal directions determined affects the properties of the beamformer e.g. less attenuation of the signals received at the microphone array from the other (unwanted) directions than if only a single principal direction is determined. The output of the beamformer 404 is provided on line 406 to the automatic gain control means 228 in the form of a single channel to be processed.

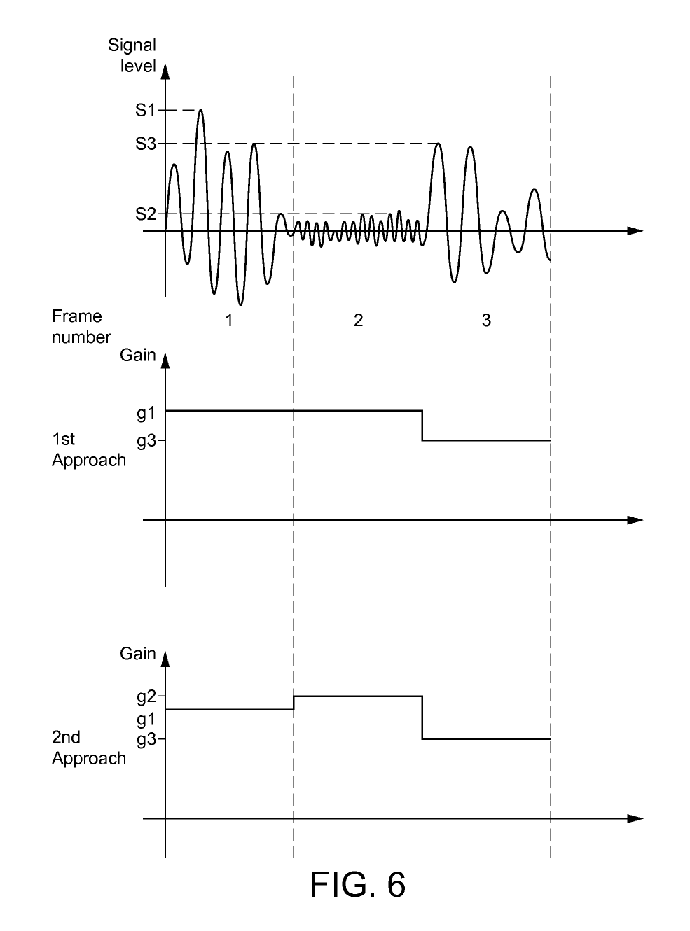

The automatic gain control means 228 applies a level of gain to the output of the beamformer. The level of gain applied to the channel output from the beamformer depends on DOA information that is received at the automatic gain control means 228. How the level of gain is determined is described later with reference to FIG. 6.

The output of the beamformer 404 may be subject to further signal processing (such as noise suppression). Circuitry for such further signal processing is not shown in FIG. 4a. The noise suppression may be applied to the amplified signal at the output of the automatic gain control means 228 before being sent to the client on line 410 for transmission over the network 106 via the network interface 226. However, it is preferable that the noise suppression be applied to the output of the beamformer before the level of gain is applied by the automatic gain control means 228 i.e. on line 406. This is because the noise suppression could theoretically slightly reduce the speech level (unintentionally) and the automatic gain control means 228 would increase the speech level after the noise suppression and compensate for the slight reduction in speech level caused by the noise suppression.

Reference is now made to FIG. 4b, which illustrates a more detailed view of microphone 208 and the automatic gain control means 228 according to an alternative embodiment.

A user may want a stereo effect using two or more independent audio channels, it is possible to provide a stereo output from a beamformer, however in some cases it may not be desirable to apply a beamformer. In this alternative embodiment a beamformer is not used.

Microphone 208 includes a plurality of microphones 402 including microphone 403 and microphone 405 and a processing block 409.

In this embodiment, audio signals are received at the plurality of microphones 402. FIG. 4b shows the plurality of microphones 402 comprising two microphones 403 and 405 for simplicity, it will be understood that this number of microphones is merely an example and is not limiting in any way.

The plurality of microphones 402 receives the audio signals on two input channels at microphones 403 and 405 respectively. The channel outputs of the microphones 403 and 405 are coupled to respective automatic gain control means 228, 229. The outputs of the microphones 403 and 405 are also coupled to processing block 409 by lines 420 422 respectively. The automatic gain control means 228, 229 apply the same level of gain to their respective channel output of the microphone 208. The level of gain applied to the output of the microphone 208 depends on DOA information that is received at the automatic gain control means 228, 229. How the level of gain is determined is described later with reference to FIG. 6.

The outputs of the microphone 208 may be subject to further signal processing (such as noise suppression). The noise suppression may be applied to the amplified signals at the output of the automatic gain control means 228,229 before being sent to the client on lines 414,415 for transmission over the network 106 via the network interface 226. However, it is preferable that the noise suppression be applied to the output of the microphone 208 before the level of gain is applied by the automatic gain control means 228, 229; an explanation of why this is preferable has been discussed above with reference to FIG. 4a.

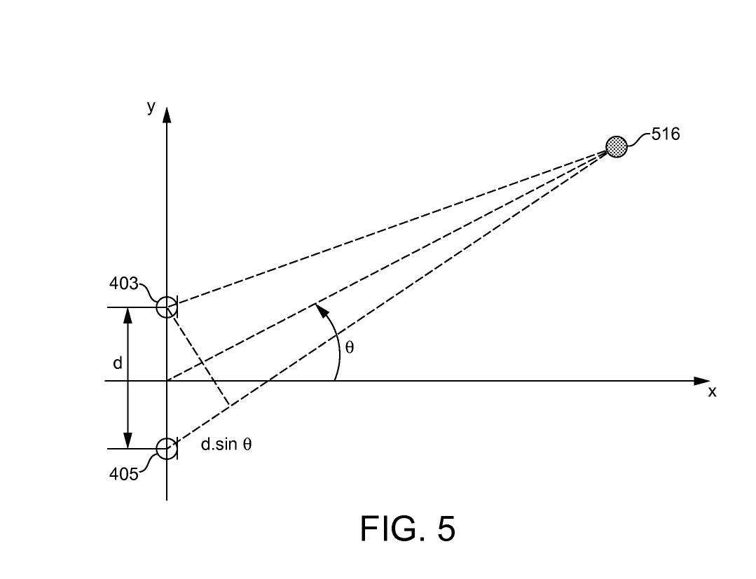

The operation of DOA estimation block 413 will now be described in more detail with reference to FIG. 5.

In the DOA estimation block 413, the DOA information is estimated by estimating the time delay e.g. using correlation methods, between received audio signals at a plurality of microphones, and estimating the source of the audio signal using the a priori knowledge about the location of the plurality of microphones.

As an example, FIG. 5 shows microphones 403 and 405 receiving audio signals on two separate input channels from an audio source 516. The direction of arrival of the audio signals at microphones 403 and 405 separated by a distance, d can be estimated using equation (1):

$$θ = arcsin ( \frac{{τ}_{D} v}{d} ) \qquad ( 1 )$$

where ν is the speed of sound, and τ_{D} is the difference between the times the audio signals from the source 516 arrive at the microphones 403 and 405—that is, the time delay. The time delay is obtained as the time lag that maximises the cross-correlation between the signals at the outputs of the microphones 403 and 405. The angle θ may then be found which corresponds to this time delay. Speech characteristics can be detected in signals received with the delay of maximum cross-correlation to determine one or more principal direction(s) of a main speaker(s).

It will be appreciated that calculating a cross-correlation of signals is a common technique in the art of signal processing and will not be describe in more detail herein.

It will be appreciated that in both the single channel and multi-channel embodiments, the invention does not require the use of a beamformer.

The operation of the automatic gain control means 228 will now be described in further detail below. For the embodiment of FIG. 4b it will be appreciated that the automatic gain control means 229 functions in the same way. In all embodiments of the invention the automatic gain control means 228 uses DOA information known at the user terminal and represented by DOA block 427 and receives an audio signal to be processed. The automatic gain control means 228 processes the audio signal on a per-frame basis. The processing performed in the automatic gain control means 228 comprises applying a level of gain to each frame of the audio signal input to the automatic gain control means 228. The level of gain applied by the automatic gain control means 228 to each frame of the audio signal depends on a comparison between the extracted DOA information of the current frame being processed, and the built up knowledge of DOA information for various audio sources known at the user terminal. The extracted DOA information is passed on alongside the frame, such that it is used as an input parameter to the automatic gain control means 228 in addition to the frame itself.

In conventional methods, the AGC processing stage may process the input audio signal on a per-frame basis but with a gain that will be allowed to smoothly vary from one sample to the next. The AGC processing stage applies a level of gain to a current frame that is being processed in dependence on a comparison between a signal level of the current frame being processed and a signal level of a frame that was processed immediately prior to the current frame, without taking into account DOA information.

If the signal level of the current frame being processed is lower than the signal level of the frame that was processed immediately prior to the current frame, the AGC processing stage will increase the level of gain and apply the increased level of gain to the current frame being processed.

If the signal level of the current frame being processed is higher than the signal level of the frame that was processed immediately prior to the current frame, the AGC processing stage will decrease the level of gain and apply the decreased level of gain to the current frame being processed.

In accordance with embodiments of the invention, the level of gain applied by the automatic gain control means 228 to the input audio signal may be affected by the DOA information in a number of ways.

Audio signals that arrive at the microphone 208 from directions which have been identified as from a wanted source are identified based on the detection of speech like characteristics and are identified as being from a principal direction of a main speaker.

The DOA information known at the user terminal may include the beam pattern 408 of the beamformer. The automatic gain control means 228 processes the audio input signal on a per-frame basis. During processing of a frame, the automatic gain control means 228 reads the DOA information of the frame to find the angle from which a main component of the audio signal in the frame was received at the microphone 208. The DOA information of the frame is compared with the DOA information 427 known at the user terminal. This comparison determines whether a main component of the audio signal in the frame being processed was received at the microphone 208 from the direction of a wanted source.

Alternatively or additionally, the DOA information 427 known at the user terminal may include the angle Ø at which farend signals are received at the microphone 208 from speakers (such as 206) at the user terminal (supplied to the automatic gain control means 228,229 on line 407).

Alternatively or additionally, the DOA information 427 known at the user terminal may be derived from a function 425 which classifies audio from different directions to locate a certain direction which is very noisy, possibly as a result of a fixed noise source.

When the DOA information 427 represents the principal wanted direction, and it is determined by comparison that a main component of the frame being processed is received at the microphone 208 from that principal direction. The automatic gain control means 228 determines a level of gain using conventional methods described above.

In a first approach, if it is determined that a main component of the frame being processed is received at the microphone 208 from a direction other than a principal direction the normal operation of the automatic gain control means 228 is inhibited and the automatic gain control means 228 applies a level of gain to the current frame being processed that was applied to the frame that was processed immediately prior to the current frame i.e. the level of gain is kept constant.

This prevents the automatic gain control means 228 adjusting the gain that is to be applied to a frame when unwanted audio signals are received at the microphone 208 during a call. Alternatively, the gain control means 228 can be prevented from increasing on frames with unwanted audio signals.

The operation of the automatic gain control means 228 according to the first approach in one example scenario is illustrated in FIG. 6.

During a call, the automatic gain control means 228 receives DOA information (beam pattern 408) that identifies a principal direction of a main speaker, and this is held in block 427. When a first frame is processed, the automatic gain control means 228 reads the DOA information of the first frame to find the angle from which a main component of the audio signal in the first frame was received at the microphone 208. The DOA information of the first frame is compared with the DOA information 427 known at the user terminal. As a result of this comparison the automatic gain control means 228 determines that a main component of the audio signal in the first frame being processed was received at the microphone 208 from the principal direction. Based on this DOA information, the automatic gain control means 228 processes the first frame (having a signal level s1) by applying a level of gain g1.

When a second frame is processed, the automatic gain control means 228 reads the DOA information of the second frame to find the angle from which a main component of the audio signal in the second frame was received at the microphone 208. The DOA information of the second frame is compared with DOA information known at the user terminal. As a result of this comparison the automatic gain control means 228 determines that a main component of the audio signal in the second frame being processed was not received at the microphone 208 from the principal direction. Based on this DOA information, the automatic gain control means 228 processes the second frame (having a signal level s2) by applying the level of gain g1 i.e. the level of gain is kept constant.

In conventional methods, as the signal level s2 of the second frame being processed is lower than the signal level s1 of the first frame (processed immediately prior to the second frame) the gain level would have increased and the increased gain level would have been applied to the audio signal in the second frame i.e. the audio signal in the second frame would have been brought up to regular speech levels.

It can usually be assumed that the signal level of speech plus noise is higher than the signal level of noise, but in rare conditions the signal level of noise in-between speech bursts can be higher than the speech. In the described embodiment, the automatic gain control means 228 uses the larger of the two to determine the gain factor.

When a third frame is processed, the automatic gain control means 228 reads the DOA information of the third frame to find the angle from which a main component of the audio signal in the third frame was received at the microphone 208. The DOA information of the third frame is compared with DOA information known at the user terminal. As a result of this comparison the automatic gain control means 228 determines that a main component of the audio signal in the third frame being processed was received at the microphone 208 from the principal direction. Based on this DOA information, the automatic gain control means 228 processes the third frame (having a signal level s3) by applying a level of gain g3.

The level of gain g3 is adjusted as in the conventional methods. In this example, the third frame has a higher signal level than the signal level of the second frame i.e. s3>s2, so the automatic gain control means 228 decreases the level of gain from g1 to g3 and applies the decreased level of gain g3 to the audio signal input to the automatic gain control means 228.

Thus in this first approach an adjustment of the level of gain by the automatic gain control means 228 may be permitted or not in dependence on whether a main component of the audio signal in the frame being processed is received at the microphone 208 from the principal direction(s).

As mentioned above, the automatic gain control means 228 may receive DOA information from a function 425 which identifies unwanted audio signals arriving at the microphone 208 from noise source(s) in different directions. These unwanted audio signals are identified from their characteristics, for example audio signals from key taps on a keyboard or a fan have different characteristics to human speech. The angle at which the unwanted audio signals arrive at the microphone 208 may be excluded from the angles that the automatic gain control means 228 may react to. Therefore when a main component of an audio signal in a frame being processed is received at the microphone 208 from an excluded direction the automatic gain control means 228 applies a level of gain to the frame being processed that was applied to a frame processed immediately prior to the current frame i.e. the level of gain is kept constant.

A verification means 423 may be further included. For example, once one or more principal directions have been detected (based on the beam pattern 408 for example in the case of a beamformer), the client informs the user 102 of the detected principal direction via the client user interface and asks the user 102 if the detected principal direction is correct. This verification is optional as indicated by the dashed line in FIG. 4a.

If the user 102 confirms that the detected principal direction is correct, then the detected principal direction is sent as DOA information to the automatic gain control means 228 and the automatic gain control means 228 operates as described above. The communication client may store the detected principal direction in memory 210, once the user 102 logs in to the client and has confirmed that a detected principal direction is correct, following subsequent log-ins to the client if a detected principal direction matches a confirmed correct principal direction in memory the detected principal direction is taken to be correct. This prevents the user 102 having to confirm a principal direction every time he logs into the client.

If the user indicates that the detected principal direction is incorrect, then the detected principal direction is not sent as DOA information to the automatic gain control means 228. In this case, the processing block 409 will continue to detect the principal direction and will only send the detected principal direction to the automatic gain control means 228 once the user 102 confirms that the detected principal direction is correct.

In the first approach, the mode of operation is such that an adjustment to the level of gain can be completely inhibited based on the DOA information.

In a second approach, the automatic gain control means 228 does not operate in such a strict mode of operation.

Instead, in this second approach, the automatic gain control means 228 may adjust the level of gain that is to be applied to a frame of the audio signal in a situation where the first approach could inhibit it; however only a small adjustment to the level of gain is made. The small adjustment to the level of gain may be implemented by taking smaller gain steps or fewer gain steps. In any case the automatic gain control means reacts, but reacts less than it would in a conventional scenario.

The operation of the automatic gain control means 228 according to the second approach in the example scenario illustrated in FIG. 6 is described below.

As in the first approach, during a call, the automatic gain control means 228 has DOA information 427 that identifies a principal direction of a main speaker. When the first frame is processed, the automatic gain control means 228 reads the DOA information of the first frame to find the angle from which a main component of the audio signal in the first frame was received at the microphone 208. The DOA information of the first frame is compared with DOA information known at the user terminal. As a result of this comparison the automatic gain control means 228 determines that a main component of the audio signal in the first frame being processed was received at the microphone 208 from the principal direction. Based on this DOA information, the automatic gain control means 228 processes the first frame (having a signal level s1) by applying a level of gain g1.

When the second frame is processed, the automatic gain control means 228 reads the DOA information of the second frame to find the angle from which a main component of the audio signal in the second frame was received at the microphone 208. The DOA information of the second frame is compared with DOA information known at the user terminal. As a result of this comparison the automatic gain control means 228 determines that a main component of the audio signal in the second frame being processed was not received at the microphone 208 from the principal direction. Based on this DOA information, the automatic gain control means 228 processes the second frame (having a signal level s2) by applying a level of gain which is higher or lower in line with conventional methods. In this example the second frame has a lower signal level than the first frame i.e. s2<s1, the automatic gain control means 228 increases the level of gain from g1 to g2 and applies the increased level of gain g2 to the second frame. This is closer to the conventional method, but in this case the change in gain Δg=g2−g1 is capped at a small amount e.g. 0.1 dB.

When the third frame is processed, the automatic gain control means 228 reads the DOA information of the third frame to find the angle from which a main component of the audio signal in the third frame was received at the microphone 208. The DOA information of the third frame is compared with DOA information known at the user terminal. As a result of this comparison the automatic gain control means 228 determines that a main component of the audio signal in the third frame being processed was received at the microphone 208 from the principal direction. Based on this DOA information, the automatic gain control means 228 processes the third frame (having a signal level s3) by applying a level of gain g3. The level of gain g3 is altered up or down in line with the conventional methods. In this example, the third frame has a higher signal level than the signal level of the second frame i.e. s3>s2, so the automatic gain control means 228 decreases the level of gain from g2 to g3 and applies the decreased level of gain g3 to the audio signal input to the automatic gain control means 228. In this case, the change from g2 to g3 is not capped, but operates to bring the frame with a signal level s3 up to regular speech levels.

In the example scenario described above, the level of gain the automatic gain control means 228 applied to the audio signal input at the automatic gain control means 228 will have decreased in small decrements or “steps”, as shown in FIG. 6. It is desired that the automatic gain control means 228 makes no adjustment to the gain when the microphone 208 receives background audio signals and smooth adjustments to the gain only when required for reaching the target level for speech. Unsmooth gain changes will affect the quality of the call; therefore the second approach has an advantage over the first approach in that it provides smoother gain control which results in improved call quality.

Whilst the embodiments described above have referred to a microphone 208 receiving audio signals from a single user 102, it will be understood that the microphone may receive audio signals from a plurality of users, for example in a conference call. In this scenario multiple sources of wanted audio signals arrive at the microphone 208.

It should be understood that the block, flow, and network diagrams may include more or fewer elements, be arranged differently, or be represented differently. It should be understood that implementation may dictate the block, flow, and network diagrams and the number of block, flow, and network diagrams illustrating the execution of embodiments of the invention.

It should be understood that elements of the block, flow, and network diagrams described above may be implemented in software, hardware, or firmware. In addition, the elements of the block, flow, and network diagrams described above may be combined or divided in any manner in software, hardware, or firmware. If implemented in software, the software may be written in any language that can support the embodiments disclosed herein. The software may be stored on any form of non-transitory computer readable medium, such as random access memory (RAM), read only memory (ROM), compact disk read only memory (CD-ROM), flash memory, hard drive, and so forth. In operation, a general purpose or application specific processor loads and executes the software in a manner well understood in the art.

While this invention has been particularly shown and described with reference to preferred embodiments, it will be understood to those skilled in the art that various changes in form and detail may be made without departing from the scope of the invention as defined by the appendant claims.

1. A method of processing audio signals during a communication session between a user device and a remote node, the method comprising:
receiving a plurality of audio signals at audio input means at the user device including at least one primary audio signal and unwanted signals;
receiving direction of arrival information of the audio signals at a gain control means;
providing to the gain control means known direction of arrival information representative of at least some of said unwanted signals;
processing the audio signals at the gain control means by applying a level of gain to generate a gain controlled signal for transmission to the remote node, wherein the level of gain applied is dependent on a comparison between the direction of arrival information of the audio signals and the known direction of arrival information.

2. The method according to claim 1, wherein the audio input means processes the plurality of audio signals to generate a single channel audio output signal comprising a sequence of frames, the gain control means processing each of said frames in sequence.

3. The method according to claim 2, wherein direction of arrival of information for a principal signal component of a current frame being processed is received at the gain control means, the method further comprising:
comparing the direction of arrival of information for the principal signal component of the current frame and the known direction of arrival information.

4. The method according to claim 3, further comprising determining whether to inhibit the activity of the gain control means based on said comparison.

5. The method according to claim 4, wherein the known direction of arrival information includes at least one direction from which far-end signals are received at the audio input means, said determination based on whether the principal signal component of the current frame is received at the audio input means from the at least one direction from which far-end signals are received at the audio input means.

6. The method according to claim 4, wherein the known direction of arrival information includes at least one classified direction, said determination based on whether the principal signal component of the current frame is received at the audio input means from the at least one classified direction.

7. The method according to claim 6, wherein the at least one classified direction is a direction from which at least one unwanted audio signal arrives at the audio input means and is identified based on the signal characteristics of the at least one unwanted audio signal.

8. The method according to claim 4, wherein the known direction of arrival information includes at least one principal direction from which the at least one primary audio signal is received at the audio input means, said determination based on whether the principal signal component of the current frame is received at the audio input means from the at least one principal direction.

9. The method according to claim 8, wherein the at least one principal direction is determined by:
determining a time delay that maximises the cross-correlation between the audio signals being received at the audio input means; and
detecting speech characteristics in the audio signals received at the audio input means with said time delay of maximum cross-correlation.

10. The method according to claim 8, wherein the audio input means comprises a beamformer arranged to:
estimate the at least one principal direction; and
process the plurality of audio signals to generate the single channel audio output signal by forming a beam in the at least one principal direction and substantially suppressing audio signals from any direction other than the principal direction.

11. The method according to claim 10, wherein the known direction of arrival information further includes the beam pattern of the beamformer.

12. The method according to claim 4, wherein if it determined from said comparison that the activity of said gain control means is to be inhibited, the gain control means configured to apply a level of gain to the current frame being processed that was applied to a frame processed immediately prior to the current frame.

13. The method according to claim 4, wherein if it determined from said comparison that the activity of said gain control means is to be inhibited, the gain control means configured to apply a level of gain to the current frame in dependence on a signal level of a frame processed immediately prior to the current frame, subject to a change in gain between the current and prior frame being capped.

14. The method according to claim 4, wherein if it determined from said comparison that the activity of said gain control means is not to be inhibited, the gain control means configured to compare a signal level of the frame processed with a signal level of a frame processed immediately prior to the current frame; and
if the signal level of the current frame is higher than the signal level of the frame processed immediately prior to the current frame, the gain control means configured to decrease a level of gain and apply the decreased level of gain to the current frame; and
if the signal level of the current frame is lower than the signal level of the frame processed immediately prior to the current frame, the gain control means configured to increase the level of gain and apply the increased level of gain to the current frame.

15. The method according to claim 1, wherein the audio input means comprises first and second audio input means, each audio input means processing the plurality of audio signals to generate an output channel, the method further comprising:
processing each output channel at respective gain control means by applying a level of gain to each output channel to generate first and second gain controlled signals for transmission to the remote node, wherein the level of gain is dependent on the comparison between the direction of arrival information of the audio signals and the known direction of arrival information, and is the same for each output channel.

16. The method according to claim 1, further comprising outputting from audio output means of the user device, audio data received at the user device from the remote node in the communication session.

17. The method according to claim 1, wherein the unwanted signals are generated by a source at the user device, said source comprising at least one of: audio output means of the user device; a source of activity at the user device wherein said activity includes clicking activity comprising button clicking activity, keyboard clicking activity, and mouse clicking activity.

18. The method according to claim 1, wherein the unwanted signals are generated by a source external to the user device.

19. The method according to claim 1, wherein the at least one primary audio signal is a speech signal received at the audio input means.

20. A user device for processing audio signals during a communication session between a user device and a remote node, the user terminal comprising:
audio input means for receiving a plurality of audio signals including a at least one primary audio signal and unwanted signals; and
gain control means for receiving direction of arrival information of the audio signals and known direction of arrival information representative of at least some of said unwanted signals, the gain control means configured to process the audio signals by applying a level of gain to generate a gain controlled signal for transmission to the remote node, wherein the level of gain applied is dependent on a comparison between the direction of arrival information of the audio signals and the known direction of arrival information.

21. A computer program product comprising computer readable instructions for execution by computer processing means at a user device for processing audio signals during a communication session between the user device and a remote node, the instructions comprising instructions stored on a non-transitory computer readable medium for:
receiving a plurality of audio signals at audio input means at the user device including at least one primary audio signal and unwanted signals;
receiving direction of arrival information of the audio signals at a gain control means;
providing to the gain control means known direction of arrival information representative of at least some of said unwanted signals; and
processing the audio signals at the gain control means by applying a level of gain to generate a gain controlled signal for transmission to the remote node, wherein the level of gain applied is dependent on a comparison between the direction of arrival information of the audio signals and the known direction of arrival information.
